(19) United States
(12) Patent Application Publication
(10) Pub. No.: US 2025/0203972 A1
(43) Pub. Date: Jun. 19, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Ryohei GEJO, Kawasaki (JP); Takahiro KATO, Shinagawa, Tokyo (JP); Tatsunori SAKANO, Tokyo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/761,952

(22) Filed: Jul. 2, 2024

(30) Foreign Application Priority Data
Dec. 14, 2023 (JP) 2023-211367

(51) Int. Cl. H01L 29/06; H01L 27/07; H01L 29/739

(52) U.S. Cl. CPC H10D 62/127; H10D 12/481; H10D 62/103; H10D 84/811

(57) ABSTRACT

A semiconductor device includes a first wiring region, a cell region, and a first boundary region between the first wiring region and the cell region. The device includes a first electrode, a second electrode, a first wiring part, a semiconductor layer, a first control electrode, a first contact region, and a second contact region. The semiconductor layer includes first to sixth semiconductor regions. The second semiconductor region includes a first boundary semiconductor part located in the first boundary region. The second semiconductor region is of a second conductivity type. The fifth semiconductor region is located in the cell region. The fifth semiconductor region is of the second conductivity type. A second-conductivity-type impurity concentration in the first boundary semiconductor part is less than a second-conductivity-type impurity concentration in the fifth semiconductor region.

### CROSS-REFERENCE TO RELATED APPLICATIONS

This application is based upon and claims the benefit of priority from Japanese Patent Application No. 2023-211367, filed on Dec. 14, 2023; the entire contents of which are incorporated herein by reference.

### FIELD

Embodiments relate to a semiconductor device.

### BACKGROUND

In a semiconductor device such as an RC-IGBT (Reverse Conducting-Insulated Gate Bipolar Transistor) or the like, breakdown of the semiconductor device may occur when an excessive current flows.

### BRIEF DESCRIPTION OF THE DRAWINGS

FIG. 1 is a schematic plan view illustrating a semiconductor device according to an embodiment;

FIG. 2 is a schematic plan view illustrating the semiconductor device according to the embodiment;

FIG. 3 is a schematic cross-sectional perspective view illustrating the semiconductor device according to the embodiment;

FIG. 4 is a schematic cross section illustrating the semiconductor device according to the embodiment;

FIG. 5 is a schematic cross section illustrating the semiconductor device according to the embodiment;

FIG. 6 is a schematic cross section illustrating the semiconductor device according to the embodiment;

FIGS. 7A and 7B are schematic graphs illustrating impurity concentration distributions in the semiconductor layer;

FIG. 8 is a schematic cross-sectional perspective view illustrating a semiconductor device according to an embodiment;

FIGS. 9A and 9B are schematic graphs illustrating impurity concentration distributions in the semiconductor layer;

FIG. 10 is a schematic cross-sectional perspective view illustrating a semiconductor device according to an embodiment;

FIG. 11 is a schematic cross-sectional perspective view illustrating a semiconductor device according to an embodiment;

FIG. 12 is a schematic plan view illustrating the semiconductor device according to the embodiment;

FIG. 13 is a schematic plan view illustrating a semiconductor device according to an embodiment;

FIG. 14 is a schematic plan view illustrating the semiconductor device according to the embodiment;

FIG. 15 is a schematic cross-sectional perspective view illustrating the semiconductor device according to the embodiment;

FIG. 16 is a schematic cross-sectional perspective view illustrating the semiconductor device according to the embodiment;

FIGS. 17A to 17C are schematic views illustrating operations of the semiconductor device according to the embodiment; and

FIG. 18 is a schematic circuit diagram illustrating a circuit using the semiconductor device according to the embodiment.

### DETAILED DESCRIPTION

A semiconductor device according to one embodiment, includes a first wiring region, a cell region, and a first boundary region between the first wiring region and the cell region. The device includes a first electrode, a second electrode, a first wiring part, a semiconductor layer, a first control electrode, a first contact region, and a second contact region. At least a portion of the second electrode is located in the first boundary region. At least a portion of the second electrode is located in the cell region. A direction from the first electrode toward the second electrode is along a first direction. A direction from the first wiring region toward the cell region is along a second direction crossing the first direction. The first wiring part is located in the first wiring region. The semiconductor layer includes a first semiconductor region, a second semiconductor region, a third semiconductor region, a fourth semiconductor region, a fifth semiconductor region, and a sixth semiconductor region. The first semiconductor region is located in the cell region, the first wiring region, and the first boundary region. The first semiconductor region is of a first conductivity type. The second semiconductor region includes a first boundary semiconductor part located in the first boundary region. At least a portion of the first boundary semiconductor part is located between the first semiconductor region and the second electrode. The second semiconductor region is of a second conductivity type. The third semiconductor region is located between the first electrode and the first semiconductor region. The third semiconductor region is of the second conductivity type. The fourth semiconductor region is located between the first electrode and the first semiconductor region. The fourth semiconductor region is of the first conductivity type. A first-conductivity-type impurity concentration in the fourth semiconductor region is greater than a first-conductivity-type impurity concentration in the first semiconductor region. The fifth semiconductor region is located in the cell region. The fifth semiconductor region is positioned between the first semiconductor region and the second electrode. The fifth semiconductor region is of the second conductivity type. The sixth semiconductor region is located in the cell region. The sixth semiconductor region is positioned between the first semiconductor region and the second electrode. The sixth semiconductor region is electrically connected with the second electrode. The sixth semiconductor region is of the first conductivity type. The first control electrode faces the first, second, and sixth semiconductor regions via a first insulating part. The first control electrode is electrically connected with the first wiring part. The first contact region is located in the first boundary region. The first contact region contacts the first boundary semiconductor part. The first contact region electrically connects the first boundary semiconductor part and the second electrode. The second contact region is located in the cell region. The second contact region contacts the fifth semiconductor region. The second contact region electrically connects the fifth semiconductor region and the second electrode. A second-conductivity-type impurity concentration in the first boundary semiconductor part is less than a second-conductivity-type impurity concentration in the fifth semiconductor region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

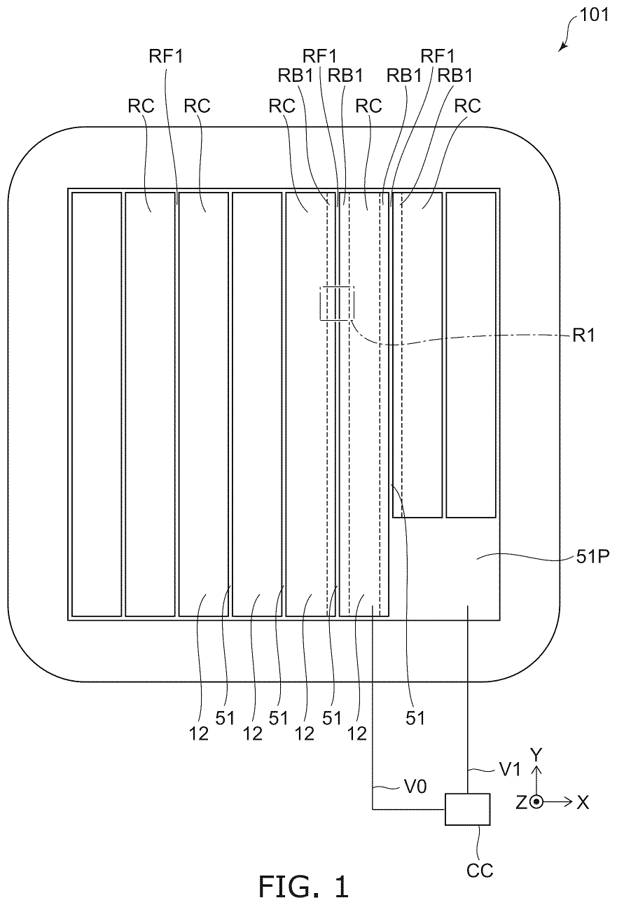

FIG. 1 is a schematic plan view illustrating a semiconductor device according to an embodiment.

The semiconductor device 101 illustrated in FIG. 1 is, for example, an RC-IGBT. Multiple first wiring regions RF1, multiple cell regions RC, and multiple first boundary regions RB1 are set in the X-Y plane in the semiconductor device 101.

The cell region RC is, for example, a region in which transistors are formed. The multiple cell regions RC are arranged in an X-direction. For example, a second electrode 12 is located in the cell region RC. For example, the second electrode 12 extends in the X-Y plane to cover substantially the entire cell region RC.

A first wiring part 51 (a gate wiring part) is located in the first wiring region RF1. For example, the first wiring region RF1 corresponds to a gate finger part. The gate finger part is a region where the gate electrode is connected to the gate wiring part. The first wiring part 51 and the first wiring region RF1 extend in a Y-direction. The multiple first wiring regions RF1 (the multiple first wiring parts 51) are arranged in the X-direction. The direction from the first wiring region RF1 toward the cell region RC is along the X-direction. The first wiring region RF1 and the cell region RC are alternately arranged in the X-direction. The cell region RC is positioned between two first wiring regions RF1 adjacent to each other in the X-direction; and the first wiring region RF1 is positioned between two cell regions RC adjacent to each other in the X-direction. The first boundary region RB1 is positioned between the first wiring region RF1 and the cell region RC adjacent to each other in the X-direction. The multiple first wiring parts 51 are electrically connected with a first electrode pad 51P.

The first boundary regions RB1 are regions respectively positioned between the first wiring regions RF1 and the cell regions RC. The first boundary region RB1 extends in the Y-direction along the first wiring region RF1. The first boundary region RB1 is continuous with the first wiring region RF1 and the cell region RC. The configuration of the first boundary region RB1 is described below.

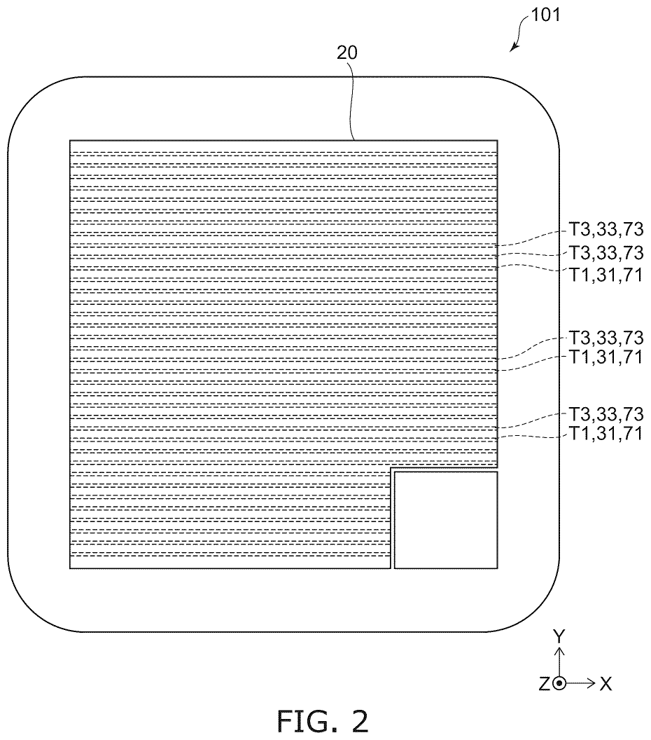

FIG. 2 is a schematic plan view illustrating the semiconductor device according to the embodiment.

In FIG. 2, the first wiring part 51, the second electrode 12, etc., are not illustrated, and the layout of the layers below the first wiring part 51 and the second electrode 12 are schematically illustrated. The semiconductor device 101 includes a semiconductor layer 20. Multiple trenches T1 are provided in the semiconductor layer 20. As described below, a first control electrode 31 (a gate electrode) and a first insulating part 71 are located inside each trench T1. In FIG. 2, the trench T1, the first control electrode 31, and the first insulating part 71 are illustrated collectively by broken lines for convenience.

The trench T1 (the first control electrode 31 and the first insulating part 71) extends in the X-direction. Each trench T1 (each first control electrode 31 and each first insulating part 71) extends through the multiple cell regions RC, the multiple first boundary regions RB1, and the multiple first wiring regions RF1 described with reference to FIG. 1. The multiple trenches T1 (the multiple first control electrodes 31 and the multiple first insulating parts 71) are arranged in the Y-direction.

Multiple trenches T3 may be provided in the semiconductor layer 20. As described below, a conductive member 33 (e.g., a dummy electrode) and an insulating part 73 are located inside each trench T3. In FIG. 2, the trench T3, the conductive member 33, and the insulating part 73 are collectively illustrated by broken lines for convenience.

Similarly to the trench T1, the trench T3 (the conductive member 33 and the insulating part 73) extends in the X-direction. Each trench T3 (each conductive member 33 and each insulating part 73) extends through the multiple cell regions RC, the multiple first boundary regions RB1, and the multiple first wiring regions RF1. The multiple trenches T3 (the multiple conductive members 33 and the multiple insulating parts 73) are arranged in the Y-direction. The trench T1 and the trench T3 are arranged in the Y-direction.

The first wiring part 51 illustrated in FIG. 1 crosses the multiple trenches T1 and the multiple trenches T3 when viewed in plan.

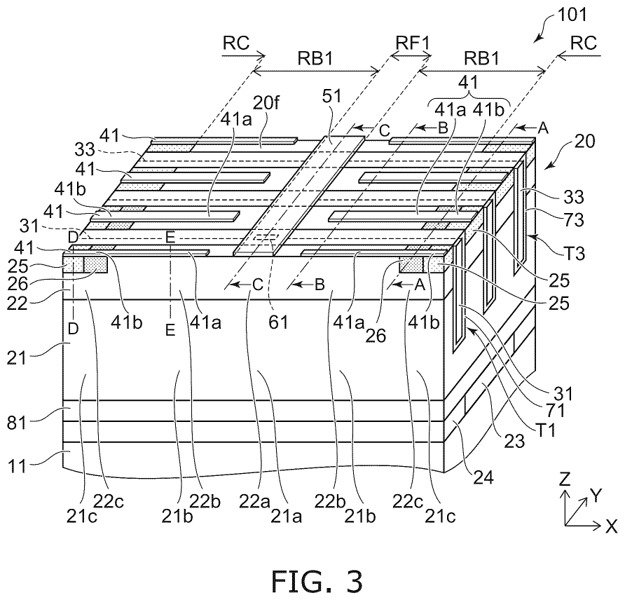

FIG. 3 is a schematic cross-sectional perspective view illustrating the semiconductor device according to the embodiment.

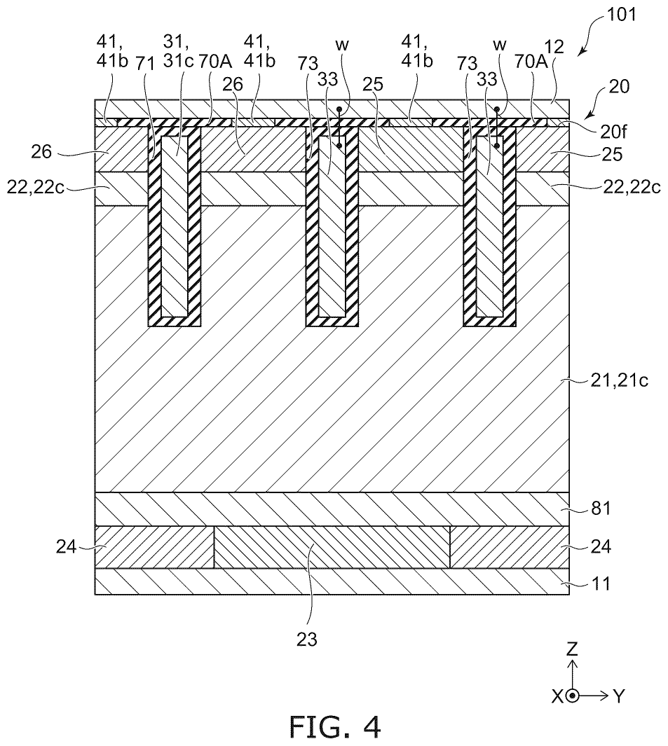

FIGS. 4, 5, and 6 are schematic cross sections illustrating the semiconductor device according to the embodiment.

FIG. 3 illustrates region R1 illustrated in FIG. 1.

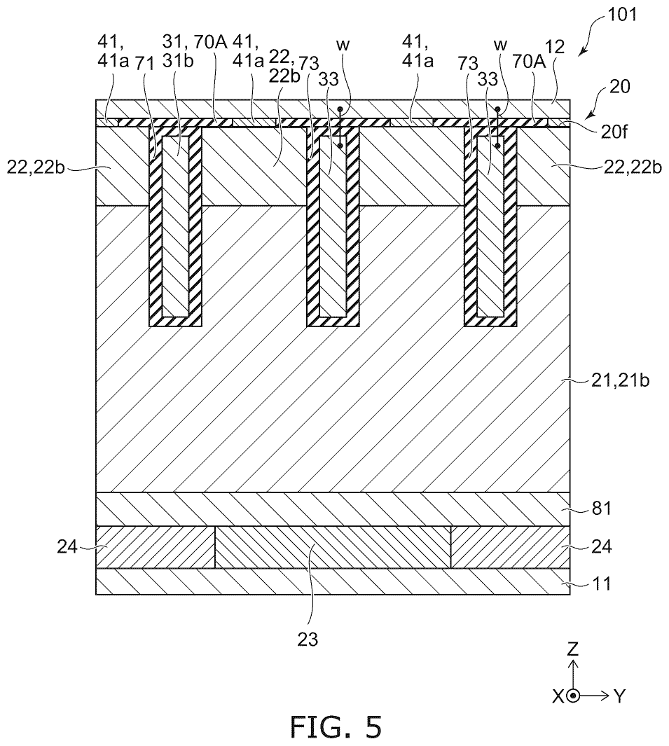

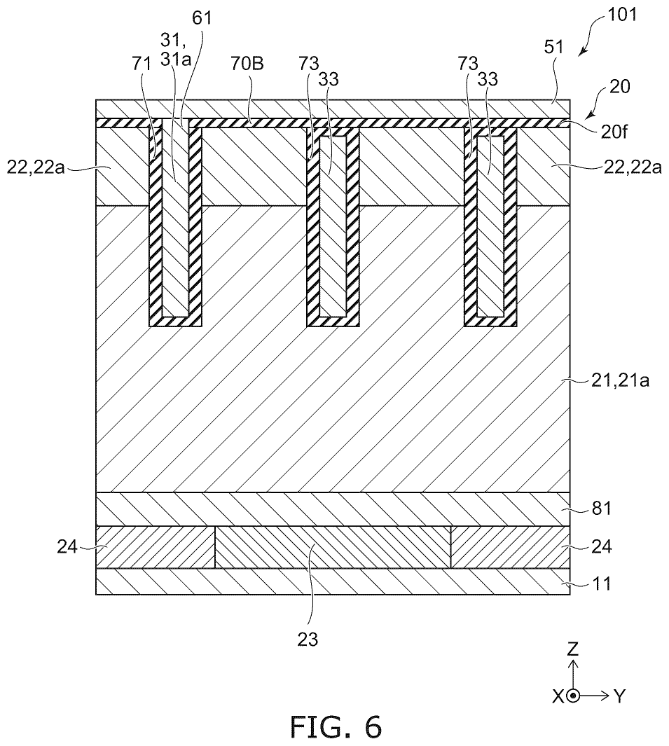

FIG. 4 illustrates a cross section along line A-A illustrated in FIG. 3. FIG. 5 illustrates a cross section along line B-B illustrated in FIG. 3. FIG. 6 illustrates a cross section along line C-C illustrated in FIG. 3.

As illustrated in FIG. 3, the semiconductor device 101 includes the first wiring part 51, the semiconductor layer 20, the first control electrode 31, and a contact part 41 (a first contact region 41a and a second contact region 41b). As illustrated in FIGS. 4 to 6, the semiconductor device 101 includes a first electrode 11 and the second electrode 12.

The direction from the first electrode 11 toward the second electrode 12 is along a Z-direction (a first direction). The Z-direction is, for example, a direction perpendicular to the upper surface of the semiconductor layer 20 (e.g., a semiconductor substrate). In the description of the embodiments, one direction crossing the Z-direction is taken as the X-direction (a second direction); and a direction crossing the Z-direction and the X-direction is taken as the Y-direction (a third direction). The X-direction and the Y-direction each may be directions perpendicular to the Z-direction. The X-direction and the Y-direction may be directions that are orthogonal to each other. The direction from the first electrode 11 toward the second electrode 12 may be called “up/above”, and the opposite direction may be called “down/below”. “Up/above” and “down/below” are based on the relative positional relationship between the first electrode 11 and the second electrode 12, and are independent of the direction of gravity.

In the following example, a first conductivity type is taken to be an n-type; and a second conductivity type is taken to be a p-type. However, according to the embodiments, the first conductivity type may be the p-type; and the second conductivity type may be the n-type.

The semiconductor layer 20 is positioned between the first electrode 11 and the second electrode 12 and between the first electrode 11 and the first wiring part 51. As illustrated in FIG. 3, the semiconductor layer 20 includes a first semiconductor region 21, a second semiconductor region 22, a third semiconductor region 23, a fourth semiconductor region 24, multiple fifth semiconductor regions 25, and multiple sixth semiconductor regions 26.

The first wiring region RF1 is, for example, an area in which the first wiring part 51 is located when viewed in plan from above (i.e., when viewed along the Z-direction). The first wiring region RF1 is a region in which the first wiring part 51 and the first control electrode 31 are connected. Components that overlap the first wiring part 51 in the Z-direction are components that are located in the first wiring region RF1. The contact part 41 (the first contact region 41a and the second contact region 41b) that electrically connect the semiconductor layer 20 and the second electrode 12 may not be located in the first wiring region RF1. The second electrode 12 may not be located in the first wiring region RF1. A semiconductor region (e.g., the sixth semiconductor region 26) that forms an emitter of a transistor may not be formed in the first wiring region RF1.

The cell region RC is a region including an area in which a semiconductor region (e.g., the sixth semiconductor region 26) used to form the emitter of the transistor is located when viewed in plan. For example, the cell region RC includes an area in which at least one of the fifth semiconductor region 25 or the sixth semiconductor region 26 is located when viewed in plan.

In the example as illustrated in FIG. 3, the position of the end of the cell region RC (the position in contact with the first boundary region RB1) is the position of the end of the sixth semiconductor region 26 at the first boundary region RB1 side or the position of the end of the fifth semiconductor region 25 at the first boundary region RB1 side. The position of the end of the cell region RC is the position of the boundary between the second semiconductor region 22 and the fifth semiconductor region 25 in the X-direction and the boundary between the second semiconductor region 22 and the sixth semiconductor region 26 in the X-direction. In other words, the sixth semiconductor region 26 or the fifth semiconductor region 25 contacts the first boundary region RB1.

The first boundary region RB1 is, for example, an area in which the end portion (the first contact region 41a) in the X-direction of the contact part 41 is located. When viewed in plan, the first boundary region RB1 does not include the area in which the first wiring part 51 is located, and does not include the area in which the fifth semiconductor region 25 and the sixth semiconductor region 26 are located. The first boundary region RB1 may not include a semiconductor region of the first conductivity type (e.g., the n-type) located on the second semiconductor region 22. As an example, the first boundary region RB1 is an area within 50 micrometers (μm) of the first wiring part 51 in the X-direction when viewed in plan.

For example, the first electrode 11 is located in the first wiring region RF1, the first boundary region RB1, and the cell region RC. As illustrated in FIGS. 4 and 5, at least a portion of the second electrode 12 is located in the cell region RC and the first boundary region RB1.

The first semiconductor region 21 is of the first conductivity type (e.g., the n-type). As illustrated in FIG. 3, the first semiconductor region 21 is located in the cell region RC, the first wiring region RF1, and the first boundary region RB1. In other words, the first semiconductor region 21 includes a semiconductor part 21a located in the first wiring region RF1, a semiconductor part 21b located in the first boundary region RB1, and a semiconductor part 21c located in the cell region RC. For example, the semiconductor part 21a is positioned between the first electrode 11 and the first wiring part 51. For example, at least a portion of the semiconductor part 21b is positioned between the first electrode 11 and the second electrode 12. For example, the semiconductor part 21c is positioned between the first electrode 11 and the second electrode 12.

The second semiconductor region 22 is of the second conductivity type (e.g., the p-type). As illustrated in FIG. 3, the first semiconductor region 21 is positioned between the second semiconductor region 22 and the first electrode 11. In the example, the second semiconductor region 22 is located in the cell region RC, the first wiring region RF1, and the first boundary region RB1. In other words, for example, the second semiconductor region 22 includes a semiconductor part (a wiring semiconductor part 22a) located in the first wiring region RF1, a semiconductor part (a boundary semiconductor part 22b) located in the first boundary region RB1, and a semiconductor part (a cell semiconductor part 22c) located in the cell region RC. The wiring semiconductor part 22a (a first wiring semiconductor part) is positioned between the first semiconductor region 21 and the first wiring part 51. At least a portion of the boundary semiconductor part 22b (a first boundary semiconductor part) is positioned between the first semiconductor region 21 and the second electrode 12. The cell semiconductor part 22c is positioned between the first semiconductor region 21 and the second electrode 12. The second semiconductor region 22 (the wiring semiconductor part 22a, the boundary semiconductor part 22b, and the cell semiconductor part 22c) may include multiple regions divided by trenches.

The second-conductivity-type impurity concentration in the wiring semiconductor part 22a may be equal to the second-conductivity-type impurity concentration in the boundary semiconductor part 22b. The second-conductivity-type impurity concentration in the cell semiconductor part 22c may be equal to the second-conductivity-type impurity concentration in the boundary semiconductor part 22b.

The third semiconductor region 23 is between the first electrode 11 and the first semiconductor region 21. The third semiconductor region 23 is located in the first wiring region RF1, the first boundary region RB1, and the cell region RC. The third semiconductor region 23 is of the second conductivity type. For example, the third semiconductor region 23 contacts the first electrode 11 and is electrically connected with the first electrode 11.

The fourth semiconductor region 24 is between the first electrode 11 and the first semiconductor region 21. The fourth semiconductor region 24 is located in the first wiring region RF1, the first boundary region RB1, and the cell region RC. The fourth semiconductor region 24 is of the first conductivity type. The first-conductivity-type impurity concentration in the fourth semiconductor region 24 is greater than the first-conductivity-type impurity concentration in the first semiconductor region 21. For example, the fourth semiconductor region 24 contacts the first electrode 11 and is electrically connected with the first electrode 11. The fourth semiconductor region 24 is arranged with the third semiconductor region 23 in a direction (e.g., the Y-direction) in the X-Y plane. For example, the multiple third semiconductor regions 23 and the multiple fourth semiconductor regions 24 are alternately arranged in the Y-direction. The direction in which the multiple trenches T1 are arranged and the direction in which the multiple third semiconductor regions 23 and the multiple fourth semiconductor regions 24 are arranged may be different.

As illustrated in FIG. 3, the fifth semiconductor region 25 is located in the cell region RC. The fifth semiconductor region 25 is of the second conductivity type. The fifth semiconductor region 25 is positioned between the first semiconductor region 21 and the second electrode 12. The fifth semiconductor region 25 is positioned between the cell semiconductor part 22c and the second electrode 12.

The second-conductivity-type impurity concentration in the boundary semiconductor part 22b second semiconductor region 22 is less than the second-conductivity-type impurity concentration in the fifth semiconductor region. The second-conductivity-type impurity concentration in the wiring semiconductor part 22a may be less than the second-conductivity-type impurity concentration in the fifth semiconductor region. The second-conductivity-type impurity concentration in the cell semiconductor part 22c may be less than the second-conductivity-type impurity concentration in the fifth semiconductor region. In other words, the second-conductivity-type impurity concentration in the fifth semiconductor region may be greater than the second-conductivity-type impurity concentration in the second semiconductor region 22.

As illustrated in FIG. 3, the sixth semiconductor region 26 is located in the cell region RC. The sixth semiconductor region 26 is of the first conductivity type. The sixth semiconductor region 26 is positioned between the first semiconductor region 21 and the second electrode 12. The sixth semiconductor region 26 is positioned between the cell semiconductor part 22c and the second electrode 12. The sixth semiconductor region 26 is adjacent to the fifth semiconductor region 25 in the X-direction.

The semiconductor layer 20 may further include a semiconductor region 81. The semiconductor region 81 is positioned between the first semiconductor region 21 and the fourth semiconductor region 24 and between the first semiconductor region 21 and the third semiconductor region 23. The semiconductor region 81 is of the first conductivity type. The first-conductivity-type impurity concentration in the semiconductor region 81 is greater than the first-conductivity-type impurity concentration in the first semiconductor region 21 and less than the first-conductivity-type impurity concentration in the fourth semiconductor region 24.

As illustrated in FIG. 3, the trench T1 is provided in the semiconductor layer 20. The trench T1 reaches the first semiconductor region 21 from an upper surface 20f (the upper surfaces of the second, fifth, and sixth semiconductor regions 22, 25, and 26) of the semiconductor layer 20. The first insulating part 71 is located at the inner wall of the trench T1. The first control electrode 31 is located inside the first insulating part 71 inside the trench T1. The first control electrode 31 is insulated from the semiconductor layer 20 by the first insulating part 71.

For example, as illustrated in FIG. 4, the first control electrode 31 includes a part (a cell electrode part 31c) located in the cell region RC. The first control electrode 31 faces the first semiconductor region 21, the second semiconductor region 22, and the sixth semiconductor region 26 via the first insulating part 71 in the cell region RC. More specifically, the direction from the cell electrode part 31c toward a portion of the semiconductor part 21c of the first semiconductor region 21 is along the Y-direction. The direction from the cell electrode part 31c toward the cell semiconductor part 22c of the second semiconductor region 22 is along the Y-direction. The direction from the cell electrode part 31c toward one of the sixth semiconductor regions 26 is along the Y-direction. The first insulating part 71 is located between the cell electrode part 31c and the semiconductor part 21c, between the cell electrode part 31c and the cell semiconductor part 22c, and between the cell electrode part 31c and the sixth semiconductor region 26.

The first control electrode 31 faces the fifth semiconductor region 25 via the first insulating part 71 in the cell region RC (see FIG. 3). The direction from the first control electrode 31 (the cell electrode part 31c) toward one of the fifth semiconductor regions 25 is along the Y-direction. The first insulating part 71 is located between the cell electrode part 31c and the fifth semiconductor region 25.

As illustrated in FIG. 3, the second contact region 41b is located in the cell region RC. For example, the multiple second contact regions 41b are arranged in the Y-direction. As illustrated in FIG. 3, the second contact region 41b is located on the fifth semiconductor region 25 and contacts the fifth semiconductor region 25. The second contact region 41b electrically connects the fifth semiconductor region 25 and the second electrode 12. In other words, the fifth semiconductor region 25 is electrically connected with the second electrode 12 via the second contact region 41b. For example, the multiple second contact regions 41b respectively contact the multiple fifth semiconductor regions 25.

As illustrated in FIGS. 3 and 4, some of the second contact regions 41b are located on the sixth semiconductor region 26 and contact the sixth semiconductor region 26. The second contact region 41b electrically connects the sixth semiconductor region 26 and the second electrode 12. In other words, the sixth semiconductor region 26 is electrically connected with the second electrode 12 via the second contact region 41b. For example, some of the second contact regions 41b respectively contact the multiple sixth semiconductor regions 26.

For example, as illustrated in FIG. 4, an insulating part 70A is located on the semiconductor layer 20. The insulating part 70A is located between the semiconductor layer 20 and the second electrode 12, between the first control electrode 31 and the second electrode 12, and between the conductive member 33 and the second electrode 12. The second electrode 12 is insulated from the first control electrode 31.

As illustrated in FIG. 5, the first control electrode 31 includes a part (a boundary electrode part 31b) located in the first boundary region RB1. The first control electrode 31 faces the first semiconductor region 21 and the second semiconductor region 22 via the first insulating part 71 in the first boundary region RB1. More specifically, the direction from the boundary electrode part 31b toward a portion of the semiconductor part 21b of the first semiconductor region 21 is along the Y-direction. The direction from the boundary electrode part 31b toward the boundary semiconductor part 22b of the second semiconductor region 22 is along the Y-direction. The first insulating part 71 is located between the boundary electrode part 31b and the semiconductor part 21b and between the boundary electrode part 31b and the boundary semiconductor part 22b.

As illustrated in FIG. 3, the first contact region 41a is located in the first boundary region RB1. For example, the multiple first contact regions 41a are arranged in the Y-direction. As illustrated in FIGS. 3 and 5, the first contact region 41a is located on the boundary semiconductor part 22b of the second semiconductor region 22 and contacts the boundary semiconductor part 22b. The first contact region 41a electrically connects the boundary semiconductor part 22b and the second electrode 12. In other words, the boundary semiconductor part 22b (the second semiconductor region 22) is electrically connected with the second electrode 12 via the first contact region 41a. For example, the multiple first contact regions 41a each contact the boundary semiconductor part 22b.

In the example as illustrated in FIG. 3, the first contact region 41a and the second contact region 41b are included in the contact part 41 extending in the X-direction. In other words, the first contact region 41a and the second contact region 41b are portions of the contact part 41. The contact part 41 is a conductive part located on the semiconductor layer 20 and electrically connects the semiconductor layer 20 and the second electrode 12. The contact part 41 may be a conductive part that is continuous with the second electrode 12, or may be formed as a continuous body with the second electrode 12.

In the example of FIG. 3, the multiple contact parts 41 are arranged in the Y-direction. The trench (e.g., the trench T1 or the trench T3) and the contact part 41 are alternately arranged in the Y-direction when viewed in plan. The first contact region 41a and the second contact region 41b extend in the X-direction. The first contact region 41a is continuous with the second contact region 41b.

For example, as illustrated in FIG. 6, the first control electrode 31 includes a part (a wiring electrode part 31a) located in the first wiring region RF1. The first control electrode 31 faces the first semiconductor region 21 and the second semiconductor region 22 via the first insulating part 71 in the first wiring region RF1. More specifically, the direction from the wiring electrode part 31a toward a portion of the semiconductor part 21a of the first semiconductor region 21 is along the Y-direction. The direction from the wiring electrode part 31a toward the wiring semiconductor part 22a of the second semiconductor region 22 is along the Y-direction. The first insulating part 71 is located between the wiring electrode part 31a and the semiconductor part 21a and between the wiring electrode part 31a and the wiring semiconductor part 22a.

For example, as illustrated in FIG. 6, the first wiring part 51 is positioned on the wiring electrode part 31a. In other words, the wiring electrode part 31a is between the first wiring part 51 and the first semiconductor region 21. The wiring electrode part 31a is electrically connected with the first wiring part 51 in the first wiring region RF1. Specifically, a conductive part 61 (a contact) that electrically connects the wiring electrode part 31a and the first wiring part 51 is included. The conductive part 61 is located between the wiring electrode part 31a and the first wiring part 51 and contacts the wiring electrode part 31a and the first wiring part 51.

For example, as illustrated in FIG. 6, an insulating part 70B is located on the semiconductor layer 20. The insulating part 70B is located between the semiconductor layer 20 and the first wiring part 51. The first wiring part 51 is insulated from the semiconductor layer 20, the second electrode 12, and the conductive member 33.

In the example as described above, the trench T3 is provided. As illustrated in FIG. 3, similarly to the trench T1, the trench T3 reaches the first semiconductor region 21 from the upper surface 20f of the semiconductor layer 20 (the upper surfaces of the second, fifth, and sixth semiconductor regions 22, 25, and 26). The insulating part 73 is located at the inner wall of the trench T3. The conductive member 33 is located inside the insulating part 73 inside the trench T3. The conductive member 33 is insulated from the semiconductor layer 20 by the insulating part 73. The depth of the trench T3 may be equal to the depth of the trench T1.

For example, as illustrated in FIG. 4, the conductive member 33 faces the first semiconductor region 21, the second semiconductor region 22, and the fifth semiconductor region 25 via the insulating part 73 in the cell region RC. The conductive member 33 is electrically connected with the second electrode 12 by a wiring part W. For example, as illustrated in FIG. 5, the conductive member 33 faces the first semiconductor region 21 and the second semiconductor region 22 via the insulating part 73 in the first boundary region RB1. For example, as illustrated in FIG. 6, the conductive member 33 faces the first semiconductor region 21 and the second semiconductor region 22 via the insulating part 73 in the first wiring region RF1. The conductive member 33 is insulated from the first wiring part 51 and the first control electrode 31. For example, the conductive member 33 functions as a member relaxing concentration of the electric field.

Examples of materials of components of the semiconductor device 101 will now be described.

The semiconductor regions (the first to sixth semiconductor regions, etc.) of the semiconductor layer 20 include silicon, silicon carbide, gallium nitride, or gallium arsenide as a semiconductor material. For example, the semiconductor layer 20 can include a silicon substrate. When silicon is used as the semiconductor material, arsenic, phosphorus, or antimony can be used as the n-type impurity. Boron can be used as the p-type impurity.

The first control electrode 31 and the conductive member 33 (and a second control electrode 32 described below) include a conductive material such as polysilicon, etc.

The insulating part 70A, the insulating part 70B, the first insulating part 71, and the insulating part 73 (and a second insulating part 72 described below) include an insulating material such as silicon oxide, etc.

The contact part 41 (the first contact region 41a, the second contact region 41b, and a third contact region 41c (described below)) includes, for example, a conductive material such as titanium, tungsten, etc.

The first wiring part 51, the first electrode 11, the second electrode 12, the first electrode pad 51P, a second electrode pad 52P, and the conductive part 61 (and a second wiring part 52, the second electrode pad 52P, and a conductive part 62 (described below)) include metals such as aluminum, etc.

As described above, the semiconductor device 101 operates as an RC-IGBT.

A voltage that is not less than a threshold is applied to the first control electrode 31 (e.g., a gate electrode) in a state in which a positive voltage with respect to the second electrode 12 (e.g., an emitter electrode) is applied to the first electrode 11 (e.g., a collector electrode). As a result, an inversion layer (an n-type inversion layer) is formed in the second semiconductor region 22 (e.g., a p-type base region); and an IGBT operation starts in the cell region RC. For example, a channel (an inversion layer) is formed in the region of the second semiconductor region 22 facing the first control electrode 31. For example, electrons flow from the second electrode 12 via the sixth semiconductor region 26 (e.g., an emitter region) and the channel toward the first semiconductor region 21 (e.g., a drift region). For example, holes flow from the first electrode 11 via the third semiconductor region 23 (e.g., a collector region) toward the first semiconductor region 21. Subsequently, when the voltage applied to the first control electrode 31 drops below the threshold, the inversion layer in the first semiconductor region 21 disappears, and the IGBT operation ends.

For example, a circuit includes the multiple semiconductor devices 101. When the IGBT operation of one semiconductor device 101 of the circuit ends, the inductance component of the circuit applies an induced electromotive force to the second electrode 12 of another semiconductor device 101. When the induced electromotive force is applied to the second electrode 12, the other semiconductor device 101 operates as a diode. In the diode operation, for example, holes flow from the second electrode 12 via the fifth semiconductor region 25 toward the second and first semiconductor regions 22 and 21. For example, electrons flow from the first electrode 11 via the fourth semiconductor region 24 (e.g., a cathode region) toward the first semiconductor region 21.

In the reverse recovery when the diode operation of the semiconductor device 101 ends, the holes that accumulated in the first semiconductor region 21 are discharged via the second semiconductor region 22, the fifth semiconductor region 25, and the contact (the first contact region 41a or the second contact region 41b) to the second electrode 12. The electrons that accumulated in the first semiconductor region 21 are discharged via the fourth semiconductor region 24 to the first electrode 11.

In the semiconductor device, for example, the holes that accumulated in the finger parts and the vicinity of the finger parts (e.g., the first wiring region RF1 and the first boundary region RB1) flow in the reverse recovery via the second semiconductor region 22 toward the first contact region 41a. Therefore, there is a risk that the current flowing through the first contact region 41a may become large. For example, there is a risk that the current may concentrate at the end portion of the first contact region 41a at the first wiring part 51 side. There is a possibility that breakdown of the semiconductor device may occur due to the flow of a large current.

In contrast, according to the embodiment as described above, the second-conductivity-type impurity concentration in the boundary semiconductor part 22b is less than the second-concentration the fifth conductivity-type impurity in semiconductor region 25. As a result, in the diode operation, injection of holes from the first contact region 41a into the semiconductor layers in the first boundary region RB1 and the first wiring region RF1 is suppressed. The accumulated carriers in the semiconductor layers in the first boundary region RB1 and the first wiring region RF1 can be reduced. For example, the flow of holes from the fifth semiconductor region 25 of the cell region RC toward the first boundary region RB1 is suppressed. By reducing the carrier concentration, the current in the first contact region 41a can be reduced in the reverse recovery of the diode. The breakdown immunity of the reverse recovery can be increased. For example, current concentration in the first contact region 41a can be suppressed.

In a reverse bias in which a positive voltage with respect to the second electrode 12 is applied to the first electrode 11, for example, holes can be discharged from the semiconductor layer 20 to the second electrode 12 via the first contact region 41a. Therefore, for example, at turn-off of the IGBT operation, holes also can be discharged from the first contact region 41a, and so current concentration is suppressed. A reduction of the breakdown immunity at turn-off of the IGBT operation is suppressed.

For example, a controller CC may be included as shown in FIG. 1. The controller CC includes, for example, a control circuit such as a CPU, etc. The controller CC is electrically connected with the first control electrode 31 via the first electrode pad 51P and the first wiring part 51. For example, the controller CC is electrically connected with the second electrode 12. The controller CC applies a voltage V1 to the first control electrode 31. The voltage of the voltage V1 and/or the first electrode 11 is referenced to the potential (a reference potential V0) of the second electrode 12. The reference potential V0 is, for example, a ground potential.

For example, the first contact region 41a may form a Schottky junction with the boundary semiconductor part 22b. When the junction between the first contact region 41a and the boundary semiconductor part 22b is a Schottky junction, the injection of holes from the first contact region 41a in the diode operation can be further suppressed. The current in the first contact region 41a in the reverse recovery can be further reduced.

For example, the second contact region 41b may form an ohmic junction with the fifth semiconductor region 25. As a result, the contact resistance in the cell region RC can be reduced.

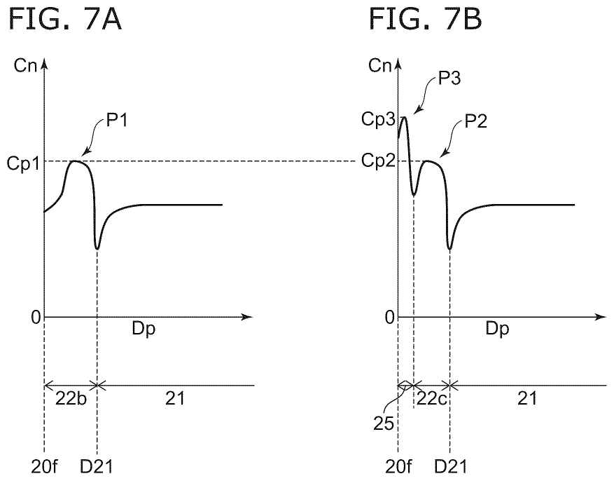

FIGS. 7A and 7B are schematic graphs illustrating distributions of an impurity concentration in the semiconductor layer.

FIG. 7A illustrates an impurity concentration along line E-E shown in FIG. 3; and FIG. 7B illustrates an impurity concentration along line D-D shown in FIG. 3. The horizontal axis illustrates a depth Dp (μm). The origin of the horizontal axis is the Z-direction position of the upper surface 20f of the semiconductor layer 20. The depth Dp corresponds to the distance along the Z-direction from the upper surface 20f. A position D21 of the horizontal axis corresponds to the boundary position between the first semiconductor region 21 and the second semiconductor region 22. The vertical axis is an impurity concentration Cn (atoms/cm³).

In FIG. 7A, the impurity concentration Cn in the range of the depth Dp from 0 to the position D21 has a second-conductivity-type impurity concentration distribution (a first distribution) along the Z-direction from the surface of the boundary semiconductor part 22b contacting the first contact region 41a to the first semiconductor region 21. The first distribution is, for example, a distribution having one peak. The first distribution includes a first peak P1.

The first peak P1 is a peak of the distribution of the impurity concentration along the Z-direction in the boundary semiconductor part 22b. The value of the first peak P1 (the second-conductivity-type impurity concentration of the first peak P1) is a first concentration Cp1.

In FIG. 7B, the impurity concentration Cn in the range of the depth Dp from 0 to the position D21 has a second-conductivity-type impurity concentration distribution (a second distribution) along the Z-direction from the surface of the fifth semiconductor region 25 contacting the second contact region 41b to the first semiconductor region 21. The number of peaks of the second distribution is greater than the number of peaks of the first distribution. The second distribution is, for example, a distribution having two peaks. The second distribution includes a second peak P2 and a third peak P3. The position of the third peak P3 is shallower than the position of the second peak P2. In other words, the Z-direction position of the third peak P3 is between the Z-direction position of the second peak P2 and the Z-direction position of the upper surface 20f of the semiconductor layer 20.

The second peak P2 is a peak of the distribution of the impurity concentration along the Z-direction in the cell semiconductor part 22c. The value of the second peak P2 (the second-conductivity-type impurity concentration of the second peak P2) is a second concentration Cp2.

The third peak P3 is a peak of the distribution of the impurity concentration along the Z-direction in the fifth semiconductor region 25. The value of the third peak P3 (the second-conductivity-type impurity concentration of the third peak P3) is a third concentration Cp3.

The height of the third peak P3 is greater than the height of the first peak P1 and greater than the height of the second peak P2. In other words, the third concentration Cp3 is greater than the first concentration Cp1 and greater than the second concentration Cp2. For example, the height of the first peak P1 (the first concentration Cp1) is not less than 0.0000001 times and not more than 0.01 times the height of the third peak P3 (the third concentration Cp3).

In FIGS. 7A and 7B, the impurity concentration Cn in the range in which the depth Dp is deeper than the position D21 corresponds to the first-conductivity-type impurity concentration along the Z-direction in the first semiconductor region 21.

Thus, the first distribution includes the low first peak P1; and the impurity concentration in the boundary semiconductor part 22b is low. As a result, the injection of holes from the first contact region 41a into the first boundary region RB1 and the first wiring region RF1 in the diode operation is suppressed. For example, the junction between the first contact region 41a and the boundary semiconductor part 22b can easily be a Schottky junction. Also, the second distribution includes the high third peak; and the impurity concentration in the fifth semiconductor region 25 is high. As a result, for example, good contact between the fifth semiconductor region 25 and the second contact region 41b can be obtained.

For example, the first concentration Cp1 is not less than 1×10¹⁴ atoms/cm³ and not more than 1×10¹⁸ atoms/cm³. The depth of the first peak P1 (the distance along the Z-direction from the upper surface 20f to the position of the first peak P1) is, for example, not less than 0.5 μm and not more than 5 μm.

For example, the second concentration Cp2 is not less than 1×10¹⁴ atoms/cm³ and not more than 1×10¹⁸ atoms/cm³. The depth of the second peak P2 (the distance along the Z-direction from the upper surface 20f to the position of the second peak P2) is, for example, not less than 0.5 μm and not more than 5 μm.

For example, the third concentration Cp3 is not less than 1×10¹⁸ atoms/cm³ and not more than 1×10²¹ atoms/cm³. The depth of the third peak P3 (the distance along the Z-direction from the upper surface 20f to the position of the third peak P3) is, for example, not less than 0.0 μm and not more than 2 μm.

For example, the impurity concentration distributions illustrated in FIGS. 7A and 7B can be formed by ion implantation. In the example, the depth of the second peak P2 is equal to the depth of the first peak P1. In the example, the height of the second peak P2 is equal to the height of the first peak P1. In other words, the first concentration Cp1 is equal to the second concentration Cp2. Although not illustrated, the impurity concentration distribution (the heights and depths of the peaks) along the Z-direction in the wiring semiconductor part 22a may be the same as the impurity concentration distribution along the Z-direction in the boundary semiconductor part 22b. For example, the wiring semiconductor part 22a, the boundary semiconductor part 22b, and the cell semiconductor part 22c can be formed by a common ion implantation process. For example, higher manufacturing costs can be suppressed.

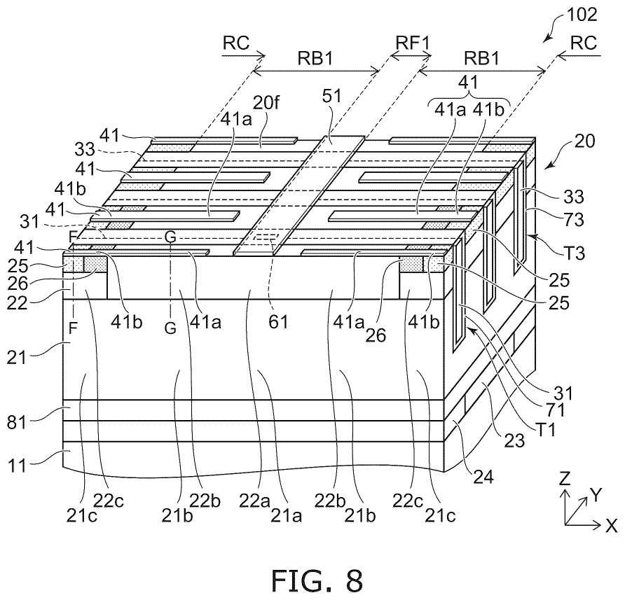

FIG. 8 is a schematic cross-sectional perspective view illustrating a semiconductor device according to an embodiment.

Similarly to FIG. 3, FIG. 8 illustrates a region of a portion of the semiconductor device 102 according to the embodiment.

In the semiconductor device 102 illustrated in FIG. 8, the distribution of the second-conductivity-type impurity concentration in the boundary semiconductor part 22b is different from the distribution of the second-conductivity-type impurity concentration in the cell semiconductor part 22c. Otherwise, the configuration of the semiconductor device 102 may be similar to that of the semiconductor device 101.

In the semiconductor device 102, for example, the second-conductivity-type impurity concentration in the boundary semiconductor part 22b is less than the second-conductivity-type impurity concentration in the cell semiconductor part 22c. The second-conductivity-type impurity concentration in the boundary semiconductor part 22b may be equal to the second-conductivity-type impurity concentration in the wiring semiconductor part 22a.

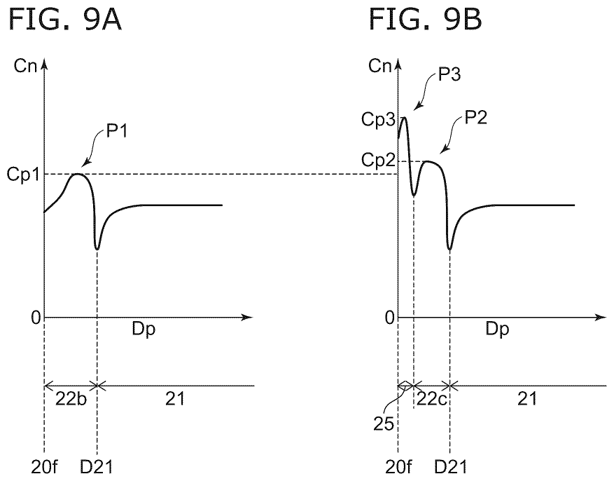

FIGS. 9A and 9B are schematic graphs illustrating impurity concentration distributions in the semiconductor layer.

FIG. 9A illustrates an impurity concentration along line G-G shown in FIG. 8; and FIG. 9B illustrates an impurity concentration along line F-F shown in FIG. 8. Similarly to FIGS. 7A and 7B, the horizontal axis is the depth Dp (μm), and the vertical axis illustrates is the impurity concentration Cn (atoms/cm³).

Similarly to FIG. 7A, FIG. 9A illustrates the second-conductivity-type impurity concentration distribution (the first distribution) along the Z-direction from the surface of the boundary semiconductor part 22b to the first semiconductor region 21 and the first-conductivity-type impurity concentration distribution along the Z-direction in the first semiconductor region 21.

Similarly to FIG. 7B, FIG. 9B illustrates the second-conductivity-type impurity concentration distribution (the second distribution) along the Z-direction from the surface of the fifth semiconductor region 25 to the first semiconductor region 21 and the first-conductivity-type impurity concentration distribution along the Z-direction in the first semiconductor region 21.

In the example, the height of the first peak P1 is less than the height of the second peak P2. In other words, the first concentration Cp1 is less than the second concentration Cp2. As a result, the injection of holes from the first contact region 41a into the first boundary region RB1 and the first wiring region RF1 in the diode operation is further suppressed. For example, the junction between the first contact region 41a and the boundary semiconductor part 22b can more easily be a Schottky junction.

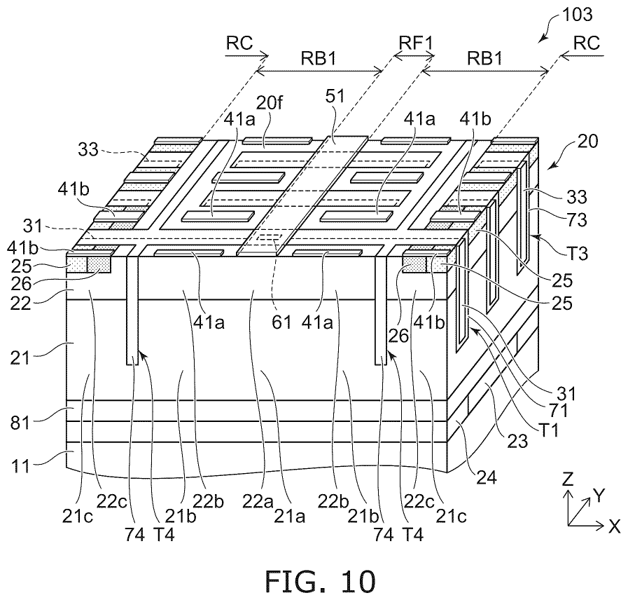

FIG. 10 is a schematic cross-sectional perspective view illustrating a semiconductor device according to an embodiment.

Similarly to FIG. 3, FIG. 10 illustrates a region of a portion of the semiconductor device 103 according to the embodiment.

In the semiconductor device 103 illustrated in FIG. 10, the semiconductor layer 20 includes a trench T4. The trench T3 (the conductive member 33 and the insulating part 73) is subdivided in the X-direction by the trench T4. The first contact region 41a and the second contact region 41b are discontinuous. Otherwise, the configuration of the semiconductor device 103 may be similar to that of the semiconductor device 101.

The trench T4 is provided in the first boundary region RB1 and extends in the Y-direction. The semiconductor layer in the first wiring region RF1 is separated from the semiconductor layer in the cell region RC by the trench T4. By dividing the semiconductor layer in the first wiring region RF1, the injection of holes into the semiconductor layer in the first wiring region RF1 is further suppressed. An increase of the current in the first contact region 41a in the reverse recovery of the diode can be further suppressed, and the breakdown immunity can be increased.

The trench T4 divides the boundary semiconductor part 22b into a portion at the first wiring region RF1 side and a portion at the cell region RC side. The first contact region 41a is separated from the second contact region 41b in the X-direction. The direction from the first contact region 41a toward the second contact region 41b is along the X-direction. The trench T4 is between the first contact region 41a and the second contact region when viewed in plan. In other words, the X-direction position of the trench T4 is between the X-direction position of the first contact region 41a and the X-direction position of the second contact region 41b.

The trench T4 is located between the fifth semiconductor region 25 and the portion of the boundary semiconductor part 22b contacting the first contact region 41a. The trench T4 separates the portion of the boundary semiconductor part 22b contacting the first contact region 41a from the fifth semiconductor region 25 and the cell semiconductor part 22c in the cell region RC. The injection of holes into the portion of the boundary semiconductor part 22b contacting the first contact region 41a is further suppressed. An increase of the current in the first contact region 41a can be further suppressed.

The trench T4 extends from the upper surface 20f of the semiconductor layer 20 toward the first semiconductor region 21 and reaches the first semiconductor region 21. In other words, the upper end of the trench T4 is positioned at the upper surface 20f of the semiconductor layer 20; and the lower end of the trench T4 contacts the first semiconductor region 21.

The trench T4 crosses the trench T1. An insulating part 74 is located inside the trench T4. The insulating part 74 is continuous with the first insulating part 71 inside the trench T1. A conductive member may be located inside the insulating part 74 inside the trench T4. The conductive member may be insulated from the semiconductor layer 20 by the insulating part 74, and may be continuous with the first control electrode 31. The depth of the trench T4 may be equal to the depth of the trench T1. The trench T4 (the insulating part 74) is separated from the trench T3 (the insulating part 73).

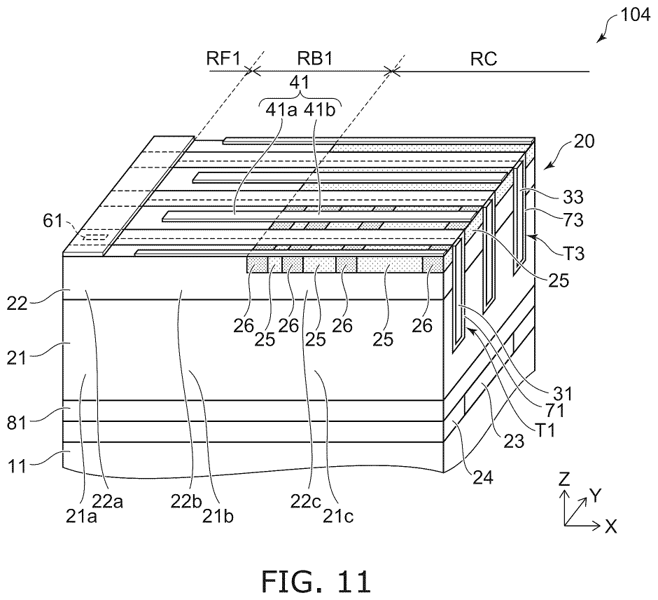

FIG. 11 is a schematic cross-sectional perspective view illustrating a semiconductor device according to an embodiment.

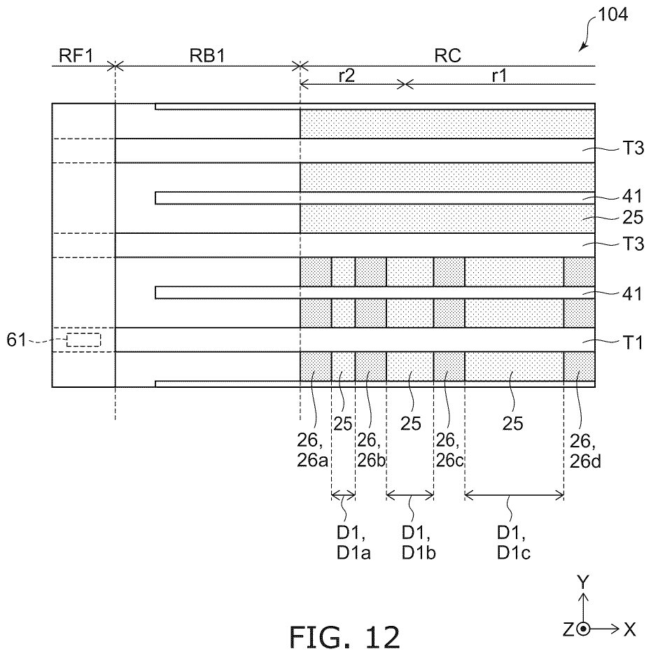

FIG. 12 is a schematic plan view illustrating the semiconductor device according to the embodiment.

FIG. 11 illustrates a region of a portion of the semiconductor device 104 according to the embodiment. FIG. 12 illustrates FIG. 11 when viewed from above.

In the semiconductor device 104 illustrated in FIGS. 11 and 12, the arrangement of the fifth and sixth semiconductor regions 25 and 26 is different from that of the semiconductor device 101 described above. Otherwise, the configuration of the semiconductor device 104 may be similar to that of the semiconductor device 101.

As illustrated in FIG. 11, the multiple sixth semiconductor regions 26 are arranged in the X-direction in the cell region RC. The fifth semiconductor region 25 and the sixth semiconductor region 26 are alternately arranged in the X-direction.

As illustrated in FIG. 12, a distance D1 between two mutually-adjacent sixth semiconductor regions 26 among the multiple sixth semiconductor regions 26 decreases toward the first boundary region RB1. More specifically, a distance D1a between a region 26a and a region 26b illustrated in FIG. 12 is less than a distance D1b between the region 26b and a region 26c. The distance D1b is less than a distance D1c between the region 26c and a region 26d. The region 26a, the region 26b, the region 26c, and the region 26d each are one of the sixth semiconductor regions 26. The region 26a, the region 26b, the region 26c, and the region 26d are arranged in this order from the first boundary region RB1 side. For example, the X-direction lengths of the sixth semiconductor regions 26 are equal.

The distance D1 between the two adjacent sixth semiconductor regions 26 corresponds to the X-direction length of the fifth semiconductor region 25 positioned between the two sixth semiconductor region. That is, the X-direction length of the fifth semiconductor region 25 decreases toward the first boundary region RB1.

For example, the density of the sixth semiconductor regions 26 in the cell region RC increases toward the first boundary region RB1. More specifically, for example, the cell region RC includes a first region r1 and a second region r2 as illustrated in FIG. 12. The second region r2 is between the first region r1 and the first boundary region RB1. When viewed in plan, the area of the sixth semiconductor region 26 per unit area in the second region r2 is greater than the area of the sixth semiconductor region 26 per unit area in the first region r1. The distance between the mutually-adjacent sixth semiconductor regions 26 in the second region r2 (e.g., the distance D1a between the regions 26a and 26b) is less than the distance between the mutually-adjacent sixth semiconductor regions 26 in the first region r1 (e.g., the distance D1c between the regions 26c and 26d).

Thus, many sixth semiconductor regions 26 are located at the first boundary region RB1 side of the cell region RC. The injection of holes at the first boundary region RB1 side of the cell region RC in the diode operation is suppressed. Accumulated carriers in the first boundary region RB1 and the first wiring region RF1 can be reduced. The current in the first contact region 41a in the reverse recovery can be further reduced. The breakdown immunity can be increased.

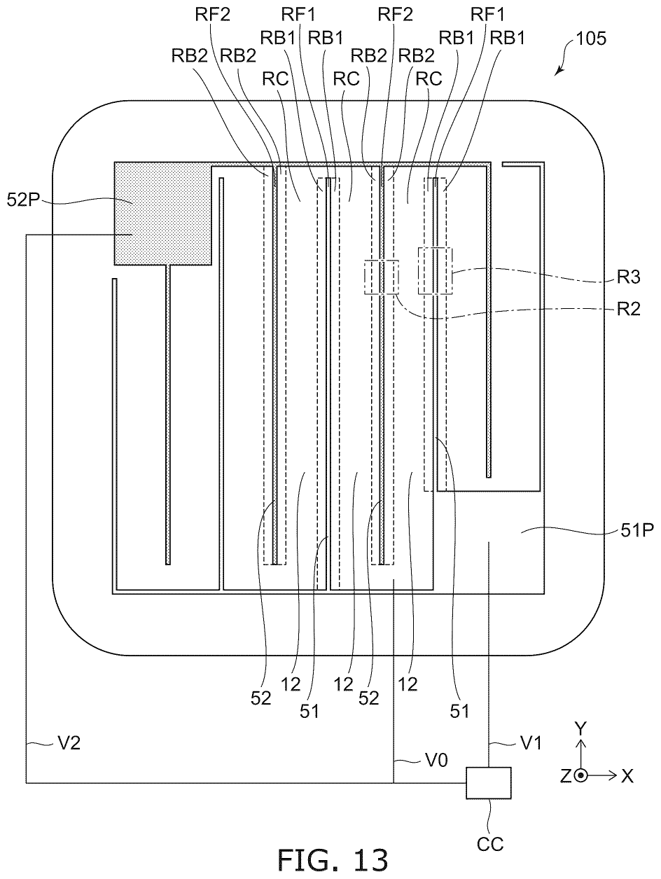

FIG. 13 is a schematic plan view illustrating a semiconductor device according to an embodiment.

Similarly to the semiconductor device 101 described above, the multiple first wiring regions RF1, the multiple cell regions RC, and the multiple first boundary regions RB1 are set in the semiconductor device 105 illustrated in FIG. 13. Multiple second wiring regions RF2 and multiple second boundary regions RB2 also are set in the semiconductor device 105.

The second wiring part 52 (a gate wiring part) is located in the second wiring region RF2. For example, the second wiring region RF2 corresponds to a gate finger part. The second wiring part 52 and the second wiring region RF2 extend in the Y-direction. The multiple second wiring regions RF2 (the multiple second wiring parts 52) are arranged in the X-direction. The direction from the cell region RC toward the second wiring region RF2 is along the X-direction. For example, the first wiring part 51 (the first wiring region RF1) and the second wiring part 52 (the second wiring region RF2) are alternately arranged in the X-direction. The cell region RC is located between the first wiring region RF1 and the second wiring region RF2. For example, the second electrode 12 is located between the first wiring part 51 and the second wiring part 52. The multiple second wiring parts 52 are electrically connected with the second electrode pad 52P. The first electrode pad 51P and the second electrode pad 52P are located on the diagonals of the substantially rectangular semiconductor device when viewed in plan.

The second boundary region RB2 is a region positioned between the second wiring regions RF2 and the cell region RC. The second boundary region RB2 extends in the Y-direction along the second wiring region RF2. The second boundary region RB2 is continuous with the second wiring region RF2 and the cell region RC.

The controller CC is electrically connected with the second control electrode 32 (described below) via the second electrode pad 52P and the second wiring part 52. The controller CC applies a voltage V2 to the second control electrode 32.

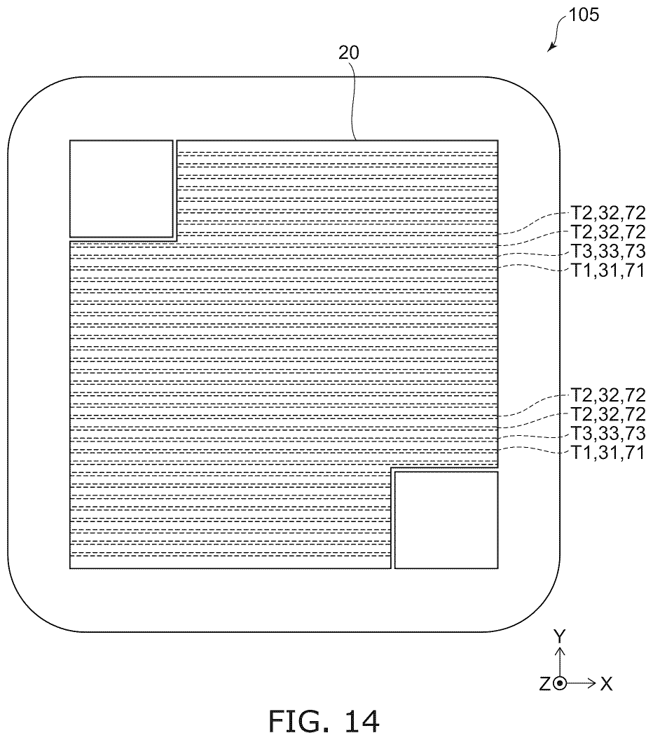

FIG. 14 is a schematic plan view illustrating the semiconductor device according to the embodiment.

In FIG. 14, the first wiring part 51, the second wiring part 52, the second electrode 12, etc., are not illustrated; and the layout of the layers below the first wiring part 51, the second wiring part 52, and the second electrode 12 is schematically illustrated.

In the example as well, the multiple trenches T1 (the first control electrodes 31 and the first insulating parts 71) and the multiple trenches T3 (the conductive members 33 and the insulating parts 73) are provided in the semiconductor layer 20. Multiple trenches T2 also are provided in the semiconductor layer 20. As described below, the second control electrode 32 (the gate electrode) and the second insulating part 72 are located inside each trench T2. In FIG. 14, the trench T2, the second control electrode 32, and the second insulating part 72 are collectively illustrated by broken lines for convenience. Similarly to FIG. 2, the trenches T1 and T3 are illustrated by broken lines.

The trench T2 (the second control electrode 32 and the second insulating part 72) extends in the X-direction. The multiple trenches T2 (the multiple second control electrodes 32 and the multiple second insulating parts 72) are arranged in the Y-direction. The trench T1, the trench T2, and the trench T3 are arranged in the Y-direction. In the example of FIG. 14, the trench T3 is located between the trench T1 and the trench T2. The trench T1 (the first control electrode 31 and the first insulating part 71), the trench T2 (the second control electrode 32 and the second insulating part 72), and the trench T3 (the conductive member 33 and the insulating part 73) extend through the multiple cell regions RC, the multiple first boundary regions RB1, the multiple first wiring regions RF1, the multiple second boundary regions RB2, and the multiple second wiring regions RF2.

The first wiring part 51 illustrated in FIG. 13 crosses the multiple trenches T1, the multiple trenches T2, and the multiple trenches T3 when viewed in plan. The second wiring part 52 illustrated in FIG. 13 crosses the multiple trenches T1, the multiple trenches T2, and the multiple trenches T3 when viewed in plan.

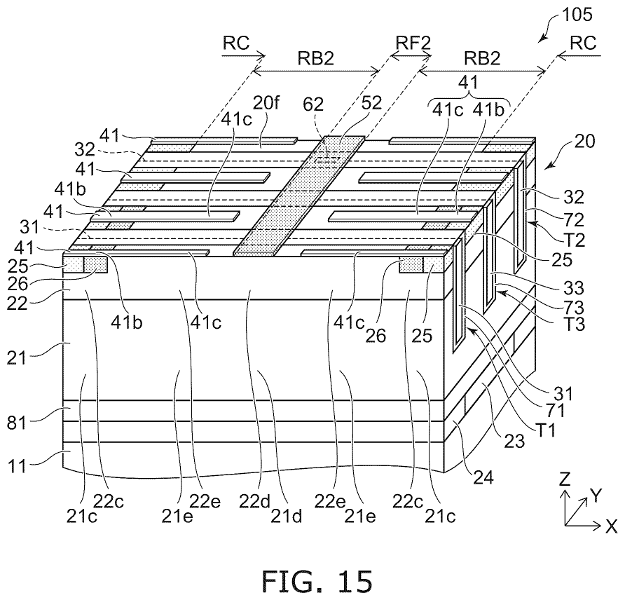

FIG. 15 is a schematic cross-sectional perspective view illustrating the semiconductor device according to the embodiment.

FIG. 15 illustrates region R2 illustrated in FIG. 13.

A portion of the semiconductor layer 20 is positioned between the first electrode 11 and the second wiring part 52. For example, the second wiring region RF2 is an area in which the second wiring part 52 is located when viewed in plan from above. The second wiring region RF2 is a region in which the second wiring part 52 and the second control electrode 32 are connected. The contact part 41 (the first contact region 41a, the second contact region 41b, and the third contact region 41c) may not be located in the second wiring region RF2. The second electrode 12 may not be located in the second wiring region RF2. A semiconductor region (e.g., the sixth semiconductor region 26) used to form an emitter of a transistor may not be formed in the second wiring region RF2.

In the example, the position of the end of the cell region RC (the position in contact with the second boundary region RB2) is at the position of the end of the sixth semiconductor region 26 at the second boundary region RB2 side or the position of the end of the fifth semiconductor region 25 at the second boundary region RB2 side. In other words, the sixth semiconductor region 26 or the fifth semiconductor region 25 contacts the second boundary region RB2.

The second boundary region RB2 is, for example, an area in which the X-direction end portion of the contact part 41 (the third contact region 41c) is located. When viewed in plan, the second boundary region RB2 does not include the area in which the second wiring part 52 is located, and does not include the area in which the fifth semiconductor region 25 and the sixth semiconductor region 26 are located. The second boundary region RB2 may not include a semiconductor region of the first conductivity type (e.g., the n-type) located on the second semiconductor region 22. As an example, the second boundary region RB2 is the area within 50 μm of the second wiring part 52 in the X-direction when viewed in plan.

A portion of the second electrode 12 also is located in the second boundary region RB2. A portion of the first electrode 11, a portion of the first semiconductor region 21, a portion of the second semiconductor region 22, a portion of the third semiconductor region 23, a portion of the fourth semiconductor region 24, and a portion of the semiconductor region 81 also are located in the second wiring region RF2 and the second boundary region RB2.

For example, the first semiconductor region 21 includes a semiconductor part 21d located in the second wiring region RF2, and a semiconductor part 21e located in the second boundary region RB2. For example, the semiconductor part 21d is positioned between the first electrode 11 and the second wiring part 52. For example, at least a portion of the semiconductor part 21e is positioned between the first electrode 11 and the second electrode 12.

For example, the second semiconductor region 22 includes a semiconductor part (a second wiring semiconductor part 22d) located in the second wiring region RF2, and a semiconductor part (a second boundary semiconductor part 22e) located in the second boundary region RB2. The second wiring semiconductor part 22d is positioned between the first semiconductor region 21 and the second wiring part 52. At least a portion of the second boundary semiconductor part 22e is positioned between the first semiconductor region 21 and the second electrode 12. The second wiring semiconductor part 22d and/or the second boundary semiconductor part 22e may include multiple regions separated by trenches.

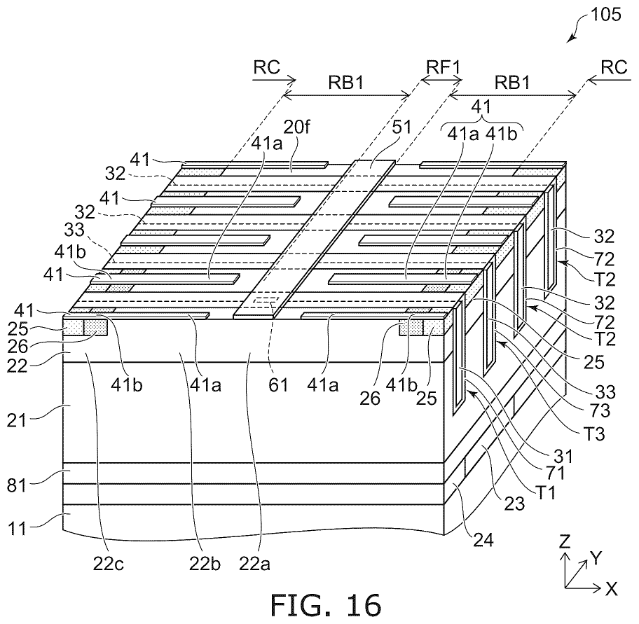

The second-conductivity-type impurity concentration and distribution along the Z-direction in the second wiring semiconductor part 22d may be similar to those of the wiring semiconductor part 22a shown in FIG. 16. The second-conductivity-type impurity concentration and distribution along the Z-direction in the second boundary semiconductor part 22e may be similar to those of the boundary semiconductor part 22b shown in FIG. 16. For example, the second-conductivity-type impurity concentration in the second boundary semiconductor part 22e is less than the second-conductivity-type impurity concentration in the fifth semiconductor region 25. For example, the second-conductivity-type impurity concentration in the second boundary semiconductor part 22e may be equal to the second-conductivity-type impurity concentration in the second wiring semiconductor part 22d.

The trench T2 reaches the first semiconductor region 21 from the upper surface 20f of the semiconductor layer 20. The second insulating part 72 is located at the inner wall of the trench T2. The second control electrode 32 is located inside the second insulating part 72 inside the trench T2. The second control electrode 32 is insulated from the semiconductor layer 20 by the second insulating part 72.

The second control electrode 32 faces the first semiconductor region 21, the second semiconductor region 22, and the fifth semiconductor region 25 via the second insulating part 72 in the cell region RC. In the cell region RC, the directions from the second control electrode 32 toward the first, second, and fifth semiconductor regions 21, 22, and 25 are along the Y-direction. The second insulating part 72 is positioned between the second control electrode 32 and the first semiconductor region 21, the second semiconductor region 22, and the fifth semiconductor region 25. The second insulating part 72 may not contact the sixth semiconductor region 26. The second control electrode 32 is insulated from the second electrode 12, the conductive member 33, the first control electrode 31, and the first wiring part 51.

The first control electrode 31 faces the first semiconductor region 21 and the second semiconductor region 22 via the first insulating part 71 in the second boundary region RB2 and the second wiring region RF2. The second control electrode 32 faces the first semiconductor region 21 and the second semiconductor region 22 via the second insulating part 72 in the second boundary region RB2 and the second wiring region RF2. The conductive member 33 faces the first semiconductor region 21 and the second semiconductor region 22 via the insulating part 73 (a third insulating part) in the second boundary region RB2 and the second wiring region RF2.

The third contact region 41c is located in the second boundary region RB2. For example, multiple third contact regions 41c are arranged in the Y-direction. The third contact region 41c is located on the second boundary semiconductor part 22e of the second semiconductor region 22 and contacts the second boundary semiconductor part 22e. The third contact region 41c electrically connects the second boundary semiconductor part 22e and the second electrode 12. In the example, the third contact region 41c is included in the contact part 41. For example, the third contact region 41c extends in the X-direction and is continuous with the second contact region 41b.

A portion of the first control electrode 31, a portion of the second control electrode 32, and a portion of the conductive member 33 are located between the second wiring part 52 and the first semiconductor region 21 in the second wiring region RF2. The second control electrode 32 is electrically connected with the second wiring part 52 in the second wiring region RF2. Specifically, a conductive part 62 (a contact) that electrically connects the second control electrode 32 and the second wiring part 52 is included. The conductive part 62 is located between the second control electrode 32 and the second wiring part 52 and contacts the second control electrode 32 and the second wiring part 52. The second wiring part 52 is insulated from the semiconductor layer 20, the second electrode 12, the first control electrode 31, and the conductive member 33.

FIG. 16 is a schematic cross-sectional perspective view illustrating the semiconductor device according to the embodiment.

FIG. 16 illustrates region R3 illustrated in FIG. 13.

The second control electrode 32 faces the first semiconductor region 21 and the second semiconductor region 22 via the second insulating part 72 in the first boundary region RB1 and the first wiring region RF1.

As illustrated in FIG. 16, for example, the number of the trenches T2 (the second control electrodes 32 and the second insulating parts 72) may be greater than the number of the trenches T1 (the first control electrodes 31 and the first insulating parts 71).

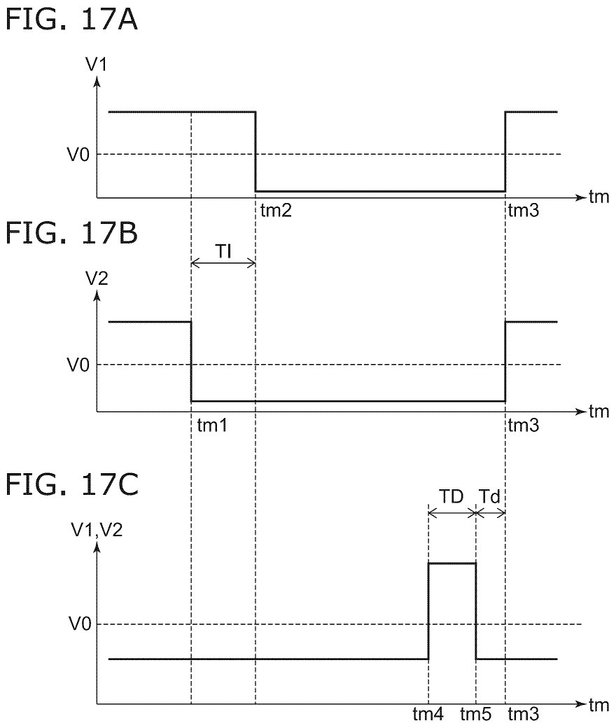

FIGS. 17A to 17C are schematic views illustrating operations of the semiconductor device according to the embodiment.

In FIGS. 17A to 17C, the horizontal axis is a time tm. FIGS. 17A and 17B illustrate the voltages V1 and V2 in the IGBT operation of one semiconductor device 105 (e.g., a first semiconductor device 105A described below). As described above, the voltage V1 is the voltage applied to the first control electrode 31; and the voltage V2 is the voltage applied to the second control electrode 32. For example, the voltage V1 and the voltage V2 are positive (the on-state) before a time tm1. At this time, for example, an n-type inversion layer is formed at the interface between the first insulating part 71 of the second semiconductor region 22 and the interface between the second insulating part 72 of the second semiconductor region 22. For example, electrons flow from the second electrode 12 toward the first semiconductor region 21 via the n-type inversion layer formed at the interface between the first insulating part 71 of the second semiconductor region 22.

For example, the voltage V2 is switched from positive to negative (the off-state) at the time tm1. As a result, for example, at the interface between the second insulating part 72 of the second semiconductor region 22, the n-type inversion layer disappears, and a p-type accumulation layer is formed. For example, at a time tm2 after the time tm1, the voltage V1 is switched from positive to negative (the off-state). As a result, for example, at the interface between the first insulating part 71 of the second semiconductor region 22, the n-type inversion layer disappears, and a p-type accumulation layer is formed. The potential of the first control electrode 31 or the second control electrode 32 in the off-state is lower than the potential of the first control electrode 31 or the second control electrode 32 in the on-state. For example, the potential of the first control electrode 31 or the second control electrode 32 in the off-state is lower than the potential (the reference potential V0) of the second electrode 12.

For example, at a time tm3 after the time tm2, the voltage V1 and the voltage V2 change from negative to positive.

Thus, in one example of the semiconductor device 105, the second control electrode 32 is switched to the off-state before the first control electrode 31 is switched to the off-state. For example, the controller CC sets the second control electrode 32 to the off-state before the first control electrode 31 is switched to the off-state. By such an operation, for example, the loss when the semiconductor device 105 is switched to the off-state can be reduced.

In a period T1 between the time tm1 and the time tm2, for example, a p-type inversion layer is formed at the interface between the second insulating part 72 of the first semiconductor region 21; and holes are discharged from the first semiconductor region 21 to the second electrode 12. By controlling the concentration of the accumulated carriers, for example, the loss when the first control electrode 31 is switched to the off-state can be reduced. As an example, the length of the period T1 (the difference between the time tm1 and the time tm2) can be not less than 10 microseconds and not more than 100 microseconds.

As described above, the number of the second control electrodes 32 may be greater than the number of the first control electrodes 31. For example, more holes can be discharged from the first semiconductor region 21 to the second electrode 12. The loss can be further reduced.

FIG. 17C illustrates the voltages V1 and V2 in the diode operation. For example, FIG. 17C illustrates the voltages V1 and V2 of another semiconductor device 105 (e.g., a second semiconductor device 105B described below) that is included in a circuit with the first semiconductor device 105A. The operations illustrated in FIGS. 17A to 17C may be repeated.

For example, in the diode operation, the voltage V1 and the voltage V2 are negative (the off-state) from the times tm1 and tm2 to a time tm4. When the voltage V1 and the voltage V2 are negative, for example, a p-type accumulation layer is formed at the interface between the first insulating part 71 of the second semiconductor region 22 and the interface between the second insulating part 72 of the second semiconductor region 22. For example, holes flow from the second electrode 12 toward the first semiconductor region 21.

At the time tm4 after the time tm2, the voltage V1 and the voltage V2 change from negative to positive (the on-state). At a time tm5 after the time tm4, the voltage V1 and the voltage V2 change again from positive to negative. The time tm5 is, for example, a time directly before the time tm3. A period Td is provided between the time tm5 and the time tm3. Thus, in the diode operation in which a current flows from the second electrode 12 toward the first electrode 11, the first control electrode 31 and the second control electrode 32 are set to the on-state. For example, the recovery loss of the diode can be reduced by such an operation.

For example, in a period TD from the time tm4 to the time tm5, at the interface between the first insulating part 71 of the second semiconductor region 22 and the interface between the second insulating part 72 of the second semiconductor region 22, the p-type accumulation layer disappears, and an n-type inversion layer is formed. As a result, for example, electrons are removed from the first semiconductor region 21 to the second electrode 12 via the n-type inversion layer at the interface between the first insulating part 71 of the second semiconductor region 22. By controlling the concentration of the accumulated carriers, for example, the loss when the diode operation ends can be reduced. As an example, the length of the period TD (the duration of the on-states of the first and second control electrodes 31 and 32) can be set to be not less than 10 microseconds and not more than 100 microseconds.

In the reverse recovery when the diode operation of the semiconductor device 105 ends, for example, a portion of the holes accumulated in the first semiconductor region 21 is discharged to the second electrode 12 via the second semiconductor region 22 and the third contact region 41c.

As described above, the second-conductivity-type impurity concentration in the second boundary semiconductor part 22e is less than the second-conductivity-type impurity concentration in the fifth semiconductor region 25. In the diode operation, the injection of holes from the third contact region 41c into the second boundary region RB2 and the second wiring region RF2 is suppressed. The accumulated carriers in the semiconductor layers in the second boundary region RB2 and the second wiring region RF2 can be reduced. The current in the third contact region 41c in the reverse recovery of the diode can be reduced. The breakdown immunity in the reverse recovery can be further improved. For example, the third contact region 41c may form a Schottky junction with the second boundary semiconductor part 22e. The injection of holes from the third contact region 41c in the diode operation can be further suppressed.

As in the period TD of FIG. 17C, by performing a gate control to switch the control electrodes on in the diode mode, the carriers in the cell region are reduced, and the current in the cell region is reduced. Accordingly, there are cases where the current relatively increases in the boundary region at the gate wiring part vicinity. For example, there are cases where current concentrates at the contact end. In contrast, according to the embodiment as described above, the second-conductivity-type impurity concentrations in the boundary semiconductor part 22b and the second boundary semiconductor part 22e are low, and the injection of holes into the boundary region is suppressed. According to the embodiment, an increase of the current at the contact end can be suppressed even when the gate control is performed.

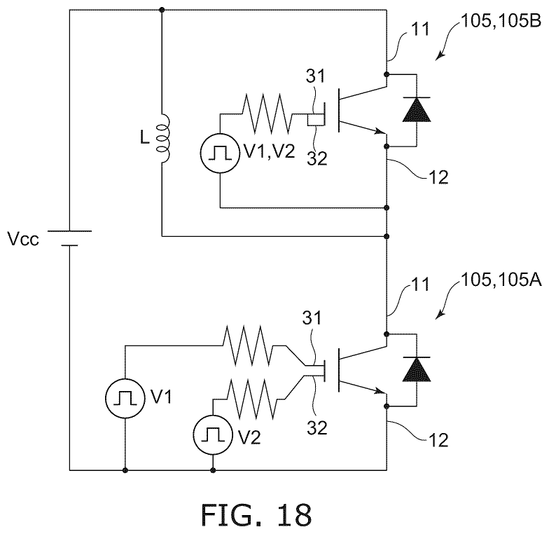

FIG. 18 is a schematic circuit diagram illustrating a circuit using the semiconductor device according to the embodiment.

As illustrated in FIG. 18, for example, a voltage Vcc, the first semiconductor device 105A, and the second semiconductor device 105B are connected in series. The first electrode 11 of the first semiconductor device 105A and the second electrode 12 of the second semiconductor device 105B are electrically connected. An inductance L is connected in parallel with the second semiconductor device 105B.

For example, the first semiconductor device 105A performs an IGBT operation. In the first semiconductor device 105A, for example, the control described with reference to FIGS. 17A and 17B is performed. For example, the second semiconductor device 105B performs a diode operation. In the second semiconductor device 105B, for example, the control described with reference to FIG. 17C is performed.

A semiconductor device that does not include the second control electrode 32 may be used. Even when the semiconductor device does not include the second control electrode 32, a gate control similarly to the voltage V1 illustrated in FIGS. 17A and 17C can be performed.

The embodiments may include the following configurations (for example, technical proposals).

### Configuration 1

A semiconductor device including a first wiring region, a cell region, and a first boundary region between the first wiring region and the cell region, the device comprising:
a first electrode;
a second electrode, at least a portion of the second electrode being located in the first boundary region, at least a portion of the second electrode being located in the cell region, a direction from the first electrode toward the second electrode being along a first direction, a direction from the first wiring region toward the cell region being along a second direction crossing the first direction;
a first wiring part located in the first wiring region;
a semiconductor layer including
   a first semiconductor region located in the cell region, the first wiring region, and the first boundary region, the first semiconductor region being of a first conductivity type,
   a second semiconductor region including a first boundary semiconductor part located in the first boundary region, at least a portion of the first boundary semiconductor part being located between the first semiconductor region and the second electrode, the second semiconductor region being of a second conductivity type,
   a third semiconductor region located between the first electrode and the first semiconductor region, the third semiconductor region being of the second conductivity type,
   a fourth semiconductor region located between the first electrode and the first semiconductor region, the fourth semiconductor region being of the first conductivity type, a first-conductivity-type impurity concentration in the fourth semiconductor region being greater than a first-conductivity-type impurity concentration in the first semiconductor region,
   a fifth semiconductor region located in the cell region and positioned between the first semiconductor region and the second electrode, the fifth semiconductor region being of the second conductivity type, and
   a sixth semiconductor region located in the cell region and positioned between the first semiconductor region and the second electrode, the sixth semiconductor region being electrically connected with the second electrode, the sixth semiconductor region being of the first conductivity type;
a first control electrode facing the first, second, and sixth semiconductor regions via a first insulating part, the first control electrode being electrically connected with the first wiring part;
a first contact region located in the first boundary region, the first contact region contacting the first boundary semiconductor part, the first contact region electrically connecting the first boundary semiconductor part and the second electrode; and
a second contact region located in the cell region, the second contact region contacting the fifth semiconductor region, the second contact region electrically connecting the fifth semiconductor region and the second electrode,
a second-conductivity-type impurity concentration in the first boundary semiconductor part being less than a second-conductivity-type impurity concentration in the fifth semiconductor region.

### Configuration 2

The device according to Configuration 1, wherein
a first distribution of a second-conductivity-type impurity concentration along the first direction from a surface of the first boundary semiconductor part contacting the first contact region to the first semiconductor region includes a first peak,
a second distribution of a second-conductivity-type impurity concentration along the first direction from a surface of the fifth semiconductor region contacting the second contact region to the first semiconductor region includes a second peak and a third peak, and
the third peak is higher than the second peak and higher than the first peak.

### Configuration 3

The device according to Configuration 2, wherein
a height of the first peak is not more than 0.01 times a height of the third peak.

### Configuration 4

The device according to Configuration 2 or 3, wherein
a height of the first peak is equal to a height of the second peak.

### Configuration 5

The device according to Configuration 2 or 3, wherein
the first peak is lower than the second peak.

### Configuration 6

The device according to any one of Configurations 1 to 5, wherein
the first contact region forms a Schottky junction with the first boundary semiconductor part.

### Configuration 7

The device according to any one of Configurations 1 to 6, wherein
the second semiconductor region includes a wiring semiconductor part located in the first wiring region,
the wiring semiconductor part is positioned between the first wiring part and the first semiconductor region, and
a second-conductivity-type impurity concentration in the wiring semiconductor part is equal to the second-conductivity-type impurity concentration in the first boundary semiconductor part.

### Configuration 8

The device according to any one of Configurations 1 to 7, wherein
the semiconductor layer includes a trench provided in the first boundary region, the trench extending in a third direction crossing the first and second directions.

### Configuration 9

The device according to Configuration 8, wherein
the trench is located between the fifth semiconductor region and a portion of the first boundary semiconductor part contacting the first contact region.

### Configuration 10

The device according to Configuration 8 or 9, wherein
the trench extends from a surface of the semiconductor layer at the second electrode side toward the first semiconductor region and reaches the first semiconductor region.

### Configuration 11

The device according to any one of Configurations 8 to 10, wherein
the first contact region is separated from the second contact region in the second direction, and
a second-direction position of the trench is between a second-direction position of the first contact region and a second-direction position of the second contact region.

### Configuration 12

The device according to any one of Configurations 1 to 11, wherein
a plurality of the sixth semiconductor regions is included,
the plurality of sixth semiconductor regions is arranged in the second direction,
the cell region includes a first region, and a second region positioned between the first region and the first boundary region, and
a distance between two mutually-adjacent sixth semiconductor regions in the second region among the plurality of sixth semiconductor regions is less than a distance between two mutually-adjacent sixth semiconductor regions in the first region among the plurality of sixth semiconductor regions.

### Configuration 13

The device according to Configuration 12, wherein
a plurality of the fifth semiconductor regions is included, and
the fifth semiconductor region and the sixth semiconductor region are alternately arranged in the second direction.

### Configuration 14

The device according to any one of Configurations 1 to 13, wherein
the first wiring part extends in a third direction crossing the first and second directions, and
the first control electrode extends in the second direction and is located in the first wiring region, the first boundary region, and the cell region.

### Configuration 15

The device according to any one of Configurations 1 to 14, further comprising:
a second wiring part located in a second wiring region, the second wiring part being insulated from the first control electrode; and
a second control electrode facing the first and second semiconductor regions via a second insulating part,
the second control electrode being electrically connected with the second wiring part and insulated from the first wiring part.

### Configuration 16

The device according to Configuration 15, wherein
a direction from the cell region toward the second wiring region is along the second direction,
the cell region is between the first wiring region and the second wiring region,
the first wiring part and the second wiring part extend in a third direction crossing the first and second directions, and
the first control electrode and the second control electrode extend in the second direction and are located in the first wiring region, the cell region, and the second wiring region.

### Configuration 17

The device according to Configuration 15 or 16, further comprising:
a third contact region,
the second semiconductor region including a second boundary semiconductor part located in a second boundary region between the cell region and the second wiring region,
the third contact region being located in the second boundary region, the third contact region contacting the second boundary semiconductor part and electrically connecting the second boundary semiconductor part and the second electrode,
a second-conductivity-type impurity concentration in the second boundary semiconductor part being less than the second-conductivity-type impurity concentration in the fifth semiconductor region.

### Configuration 18

The device according to any one of Configurations 15 to 17, wherein
a plurality of the first control electrodes is included,
a plurality of the second control electrodes is included, and
a number of the plurality of second control electrodes is greater than a number of the plurality of first control electrodes.

### Configuration 19

The device according to any one of Configurations 15 to 18, wherein
the second control electrode is switched to an off-state before the first control electrode is switched to an off-state.

### Configuration 20

The device according to any one of Configurations 1 to 19, wherein
the first control electrode is switched to an on-state when a current flows from the second electrode toward the first electrode.

### Configuration 21

The semiconductor device according to any one of Configurations 1 to 20, further comprising:
a conductive member facing the first and second semiconductor regions via a third insulating part,
the conductive member being electrically connected with the second electrode.

Information that relates to the configurations of the semiconductor regions, etc., in the embodiments is obtained by, for example, electron microscopy, etc. Information that relates to the impurity concentrations of the materials and semiconductor regions is obtained by, for example, EDX (Energy Dispersive X-ray Spectroscopy), SIMS (Secondary Ion Mass Spectrometry), etc. Information that relates to the carrier concentrations in the semiconductor regions is obtained by, for example, SCM (Scanning Capacitance Microscopy), etc.

According to embodiments, a semiconductor device can be provided in which the breakdown immunity can be increased.

In this specification, being “electrically connected” includes not only the case of being connected in direct contact, but also the case of being connected via another conductive member, etc.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

When one direction is along the other direction, the one direction and the other direction may be parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device including a first wiring region, a cell region, and a first boundary region between the first wiring region and the cell region, the device comprising:
a first electrode;
a second electrode, at least a portion of the second electrode being located in the first boundary region, at least a portion of the second electrode being located in the cell region, a direction from the first electrode toward the second electrode being along a first direction, a direction from the first wiring region toward the cell region being along a second direction crossing the first direction;
a first wiring part located in the first wiring region;
a semiconductor layer including
a first semiconductor region located in the cell region, the first wiring region, and the first boundary region, the first semiconductor region being of a first conductivity type,
a second semiconductor region including a first boundary semiconductor part located in the first boundary region, at least a portion of the first boundary semiconductor part being located between the first semiconductor region and the second electrode, the second semiconductor region being of a second conductivity type,
a third semiconductor region located between the first electrode and the first semiconductor region, the third semiconductor region being of the second conductivity type,
a fourth semiconductor region located between the first electrode and the first semiconductor region, the fourth semiconductor region being of the first conductivity type, a first-conductivity-type impurity concentration in the fourth semiconductor region being greater than a first-conductivity-type impurity concentration in the first semiconductor region,
a fifth semiconductor region located in the cell region and positioned between the first semiconductor region and the second electrode, the fifth semiconductor region being of the second conductivity type, and
a sixth semiconductor region located in the cell region and positioned between the first semiconductor region and the second electrode, the sixth semiconductor region being electrically connected with the second electrode, the sixth semiconductor region being of the first conductivity type;
a first control electrode facing the first, second, and sixth semiconductor regions via a first insulating part, the first control electrode being electrically connected with the first wiring part;
a first contact region located in the first boundary region, the first contact region contacting the first boundary semiconductor part, the first contact region electrically connecting the first boundary semiconductor part and the second electrode; and
a second contact region located in the cell region, the second contact region contacting the fifth semiconductor region, the second contact region electrically connecting the fifth semiconductor region and the second electrode,
a second-conductivity-type impurity concentration in the first boundary semiconductor part being less than a second-conductivity-type impurity concentration in the fifth semiconductor region.

2. The device according to claim 1, wherein
a first distribution of a second-conductivity-type impurity concentration along the first direction from a surface of the first boundary semiconductor part contacting the first contact region to the first semiconductor region includes a first peak,
a second distribution of a second-conductivity-type impurity concentration along the first direction from a surface of the fifth semiconductor region contacting the second contact region to the first semiconductor region includes a second peak and a third peak, and
the third peak is higher than the second peak and higher than the first peak.

3. The device according to claim 2, wherein
a height of the first peak is not more than 0.01 times a height of the third peak.

4. The device according to claim 2, wherein
a height of the first peak is equal to a height of the second peak.

5. The device according to claim 2, wherein
the first peak is lower than the second peak.

6. The device according to claim 1, wherein
the first contact region forms a Schottky junction with the first boundary semiconductor part.

7. The device according to claim 1, wherein
the second semiconductor region includes a wiring semiconductor part located in the first wiring region,
the wiring semiconductor part is positioned between the first wiring part and the first semiconductor region, and
a second-conductivity-type impurity concentration in the wiring semiconductor part is equal to the second-conductivity-type impurity concentration in the first boundary semiconductor part.

8. The device according to claim 1, wherein
the semiconductor layer includes a trench provided in the first boundary region, the trench extending in a third direction crossing the first and second directions.

9. The device according to claim 8, wherein
the trench is located between the fifth semiconductor region and a portion of the first boundary semiconductor part contacting the first contact region.

10. The device according to claim 8, wherein
the trench extends from a surface of the semiconductor layer at the second electrode side toward the first semiconductor region and reaches the first semiconductor region.

11. The device according to claim 8, wherein
the first contact region is separated from the second contact region in the second direction, and
a second-direction position of the trench is between a second-direction position of the first contact region and a second-direction position of the second contact region.

12. The device according to claim 1, wherein
a plurality of the sixth semiconductor regions is included,
the plurality of sixth semiconductor regions is arranged in the second direction,
the cell region includes a first region, and a second region positioned between the first region and the first boundary region, and
a distance between two mutually-adjacent sixth semiconductor regions in the second region among the plurality of sixth semiconductor regions is less than a distance between two mutually-adjacent sixth semiconductor regions in the first region among the plurality of sixth semiconductor regions.

13. The device according to claim 12, wherein
a plurality of the fifth semiconductor regions is included, and
the fifth semiconductor region and the sixth semiconductor region are alternately arranged in the second direction.

14. The device according to claim 1, wherein
the first wiring part extends in a third direction crossing the first and second directions, and
the first control electrode extends in the second direction and is located in the first wiring region, the first boundary region, and the cell region.

15. The device according to claim 1, further comprising:
a second wiring part located in a second wiring region, the second wiring part being insulated from the first control electrode; and
a second control electrode facing the first and second semiconductor regions via a second insulating part,
the second control electrode being electrically connected with the second wiring part and insulated from the first wiring part.

16. The device according to claim 15, wherein
a direction from the cell region toward the second wiring region is along the second direction,
the cell region is between the first wiring region and the second wiring region,
the first wiring part and the second wiring part extend in a third direction crossing the first and second directions, and
the first control electrode and the second control electrode extend in the second direction and are located in the first wiring region, the cell region, and the second wiring region.

17. The device according to claim 15, further comprising:
a third contact region,
the second semiconductor region including a second boundary semiconductor part located in a second boundary region between the cell region and the second wiring region,
the third contact region being located in the second boundary region, the third contact region contacting the second boundary semiconductor part and electrically connecting the second boundary semiconductor part and the second electrode,
a second-conductivity-type impurity concentration in the second boundary semiconductor part being less than the second-conductivity-type impurity in concentration the fifth semiconductor region.

18. The device according to claim 15, wherein
a plurality of the first control electrodes is included,
a plurality of the second control electrodes is included, and
a number of the plurality of second control electrodes is greater than a number of the plurality of first control electrodes.

19. The device according to claim 15, wherein
the second control electrode is switched to an off-state before the first control electrode is switched to an off-state.

20. The device according to claim 1, wherein
the first control electrode is switched to an on-state when a current flows from the second electrode toward the first electrode.
